(19) United States
(12) Patent Application Publication
(10) Pub. No.: US 2026/0033339 A1
(43) Pub. Date: Jan. 29, 2026

(54) SCALABLE THREE-DIMENSIONAL PROCESSING ARCHITECTURE AND PACKAGE

(71) Applicant: Eridu Corporation, Saratoga, CA (US)

(72) Inventors: Ting-Kuang Chiang, Saratoga, CA (US); Drew Perkins, Saratoga, CA (US)

(21) Appl. No.: 19/224,653

(22) Filed: May 30, 2025

Related U.S. Application Data
(60) Provisional application No. 63/653,409, filed on May 30, 2024.

(51) Int. Cl. H01L 23/473; H01L 23/538; H01L 25/065; H01L 25/16

(52) U.S. Cl. CPC H01L 23/473; H01L 23/5384; H01L 23/5386; H01L 25/0652; H01L 25/16

(57) ABSTRACT

Consistent with the present disclosure, a scalable high density package is provided in which peripheral devices are provided within the same footprint or area as core logic, e.g., switching circuitry by providing the peripheral devices can be placed on the top or bottom of one or more core-I/O chips. In addition, a liquid cooled heatsink may be provided, in one example, between the core-I/O chips and the peripheral devices. A substrate, such as a printed circuit board may also be provided, such that the core-I/O chips and heatsink are provided on one side of the substrate and power supplies are provided on the other side. Conductors provided in vias that extend through the heatsink deliver power, such as a current, to the core-VO chips and the peripheral devices. Each of the foregoing circuits, therefore, is provided in a vertical arrangement to thereby provide reduce the size of the package.

This application claims priority to the U.S. provisional application identified by Ser. No. 63/653,409, filed May 30, 2024, entitled “SCALABLE THREE-DIMENSIONAL PROCESSING ARCHITECTURE AND PACKAGE”, the entire contents of which are hereby incorporated by reference herein.

### BACKGROUND

### A. Technical Field

The present disclosure relates generally to a scalable three-dimensional processing architecture and package. More particularly, the present disclosure relates to systems and methods related to high-bandwidth processing cores with three-dimensionally distributed peripheral devices, power supplies and liquid heatsinks within the corresponding architecture and package.

### B. Background

The importance of high-bandwidth processing architectures is well understood by one of skill in the art as processor intensive applications and technologies continue to grow. For example, large data centers and artificial intelligence applications require massive amounts of data processing bandwidth to support the throughput required by these systems. Most experts believe that these bandwidth hungry applications will continue to grow across different markets and technologies such that further strain is anticipated on the processing architectures that support these applications.

Processing architectures must address system latency, size and heat management as these systems scale to support the ever-increasing processing demand. These issues complicate the currently deployed processor systems' ability to scale due to a direct correlation between scaling processing architecture size and the corresponding increase in latency, size and heat generated therefrom.

FIG. 1 illustrates an exemplary prior art processor architecture 130 used in many systems. As shown, a processing system comprises a processor core 140 that is surrounded by a plurality of input/output (hereinafter, “I/O”) interfaces. These I/O interfaces couple the core 140 to a plurality of peripheral devices 110 that provide functionality to support the operation of the core 140. In this illustration, the I/O interfaces are integrated with the core 140 in the same physical device. The I/O interfaces and the core are separated logically by the dashed line in the figure. However, they can be tangled in the physical implementation. The I/O interfaces and the core can also be physically separated into separated devices. A peripheral device 110 may be memory, such as a memory element within a distributed memory architecture, a co-processor, an application-specific processing element, a communication device such as an electrical transceiver or an optical transceiver for communicating with other devices or systems far away from the core 140, or other types of peripheral devices known to one of skill in the art. Communication, such as data and control information, is transmitted between a peripheral device 110 and an I/O interface of the core 140 using a trace 120.

The length and other characteristics of the trace 120 will affect the performance of the system 130. For example, system 130 may be adversely affected as a trace 120 length increases. This trace 120 length may affect latency, signal degradation, power requirements and heat generation placed upon the processing system 130. Increased trace 120 length may also expand a corresponding package footprint surrounding the processing system 130. Accordingly, scaling the size and bandwidth of prior art processing systems 130 is complicated as the number of peripheral devices 110 increase such that the length of traces may be significantly lengthened that support the additional peripheral devices.

FIG. 2 illustrates one example of how increasing the number of peripheral devices within a processing system 230 results in a subset of trace lengths increasing. As shown, system 230 comprises a processing core 140 with corresponding I/O interfaces that are coupled a plurality of peripheral devices 110, 210. In this example, a plurality of new peripheral devices 210 is added and placed horizontally (two-dimensionally) within the architecture of the system with the intent of improving performance and bandwidth.

The new peripheral devices 210 are located at a further distance from the core 140 due to the limitations of two-dimensional scaling. The new peripheral devices 210 are shown as being peripheral devices N+1 through N+M. Traces 220 between the new peripheral devices 210 and the core 140 are longer relative to previously discussed traces 120. These new peripheral devices 210 and corresponding traces 220 result in an increase in footprint size, power requirements, signal degradation and heat across the system 230.

FIG. 3A illustrates another example of how increasing the number of peripheral devices within a processing system 230 results in trace lengths increasing. As shown, system 330 comprises a processing core 140 with corresponding I/O interfaces that are coupled to a plurality of peripheral devices 110, 310. In this example, a plurality of new peripheral devices 310 is added by extending the distance of all the peripherals 110, 310 from the core 140. Once again, this placement of additional peripheral devices 310 is performed horizontally (two-dimensionally) within the architecture of the system with the intent of improving performance and bandwidth.

Similar to the previous example, the increase in the number of peripherals and corresponding bandwidth of the system results in the average length of each trace 320 that couples a peripheral 110, 310 to the core 140. The new peripheral devices 310 are shown as being peripheral devices N+1 through N+M. Once again, these new traces 320 result in an increase in footprint size, power requirements, signal degradation and heat across the system 330.

Current processing architectures struggle to balance scaling processing bandwidth and minimizing the resulting negative performance consequences of two-dimensional additions of peripherals that support the processing core 140.

FIG. 3B illustrates a single core architecture 380 and a multi-core architecture 370 (e.g., 4 cores) that face the scalability issues described above.

Accordingly, what is needed are systems and methods that facilitate scaling of prior art processing systems while reducing the negative consequences of increasing peripheral devices within an architecture and package.

### BRIEF DESCRIPTION OF THE DRAWINGS

References will be made to embodiments of the disclosure, examples of which may be illustrated in the accompanying figures. These figures are intended to be illustrative, not limiting. Although the accompanying disclosure is generally described in the context of these embodiments, it should be understood that it is not intended to limit the scope of the disclosure to these particular embodiments. Items in the figures may be not to scale.

FIG. 1 is a prior art diagram of a processing architecture currently deployed in computational systems.

FIG. 2 is a first example of a prior art, two-dimensional scaling approach of processing architectures.

FIG. 3A is a second example of a prior art, two-dimensional scaling approach of processing architectures.

FIG. 3B illustrates a single core architecture and a multi-core architecture.

FIG. 4A illustrates a general example of a three-dimensional processing architecture comprising a plurality of peripheral devices and power supplies.

FIG. 4B illustrates an example of an integrated processing core and plurality of I/O interfaces.

FIG. 4C illustrates an example of a discrete processing core and plurality of I/O interfaces.

FIG. 5 illustrates a processing architecture in which peripheral devices and power supplies are distributed three-dimensionally around a core/IO according to various embodiments of the present disclosure.

FIG. 6 is a cross-sectional view of a processing architecture that comprises core, I/O (integrated or discrete), peripheral devices and power supplies according to various embodiments of the present disclosure.

FIG. 7A illustrates embodiments in which a liquid heatsink may be integrated within a three-dimensional processing architecture according to various embodiments of the present disclosure.

FIG. 7B illustrates a general example of a liquid cooling subsystem according to various embodiments of the present disclosure.

FIG. 7C illustrates an internal view of a liquid heatsink according to various embodiments of the present disclosure.

FIG. 7D illustrates a cross-section of a heatsink consistent with the present disclosure.

FIGS. 7E and 7F show a method for manufacturing a liquid heatsink according to various embodiments of the present disclosure.

FIG. 8 illustrates a first example of a three-dimensional processing architecture according to various embodiments of the present disclosure.

FIG. 9 illustrates a second example of a three-dimensional processing architecture according to various embodiments of the present disclosure.

FIG. 10A illustrates a third example of a three-dimensional processing architecture according to various embodiments of the present disclosure.

FIG. 10B illustrates a fourth example of a three-dimensional processing architecture according to various embodiments of the present disclosure.

FIG. 11 illustrates a first example of a three-dimensional multi-core processing architecture according to various embodiments of the present disclosure.

FIG. 12 illustrates a second example of a three-dimensional processing architecture according to various embodiments of the present disclosure.

FIGS. 13A-13D illustrates additional examples of a three-dimensional processing architecture according to various embodiments of the present disclosure.

FIG. 14 is an example of a top view of a three-dimensional processing architecture according to various embodiments of the present disclosure.

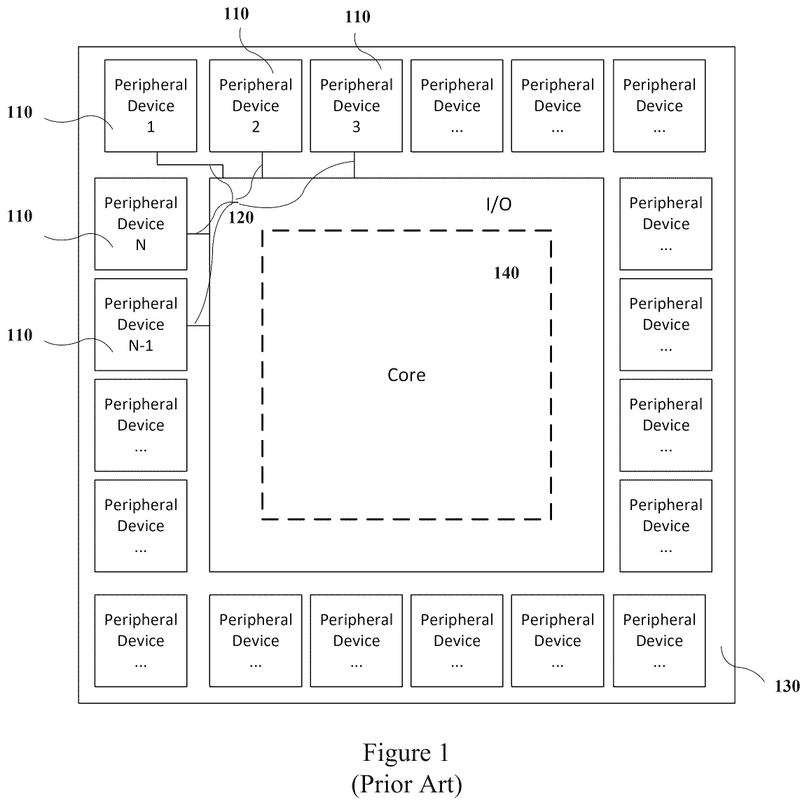

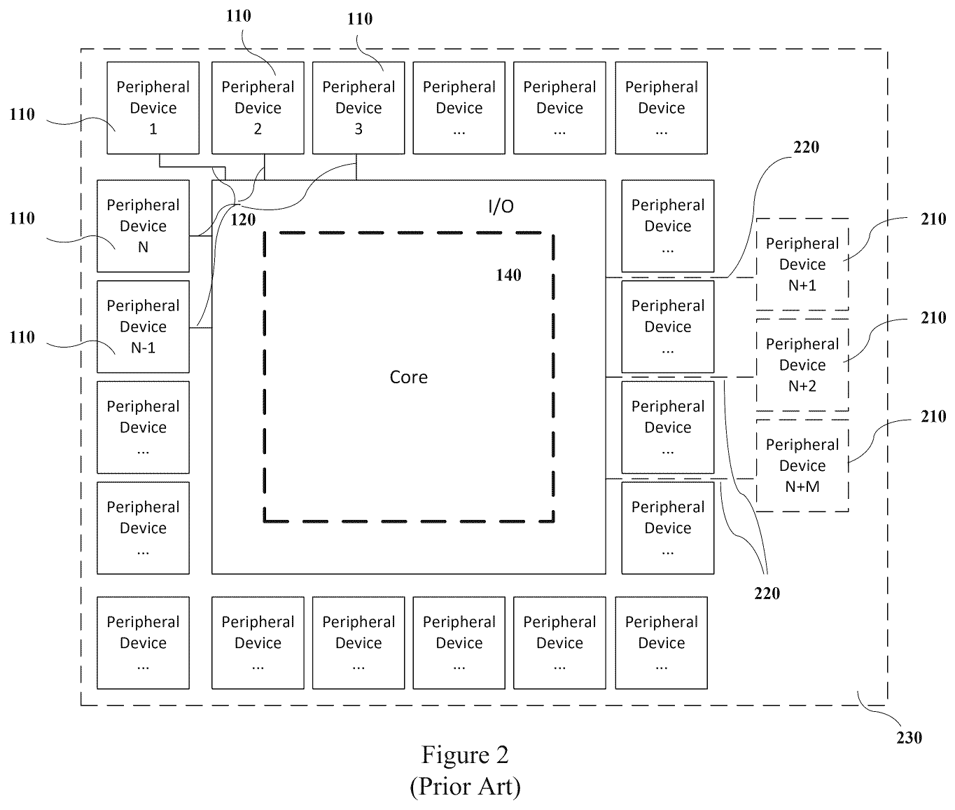

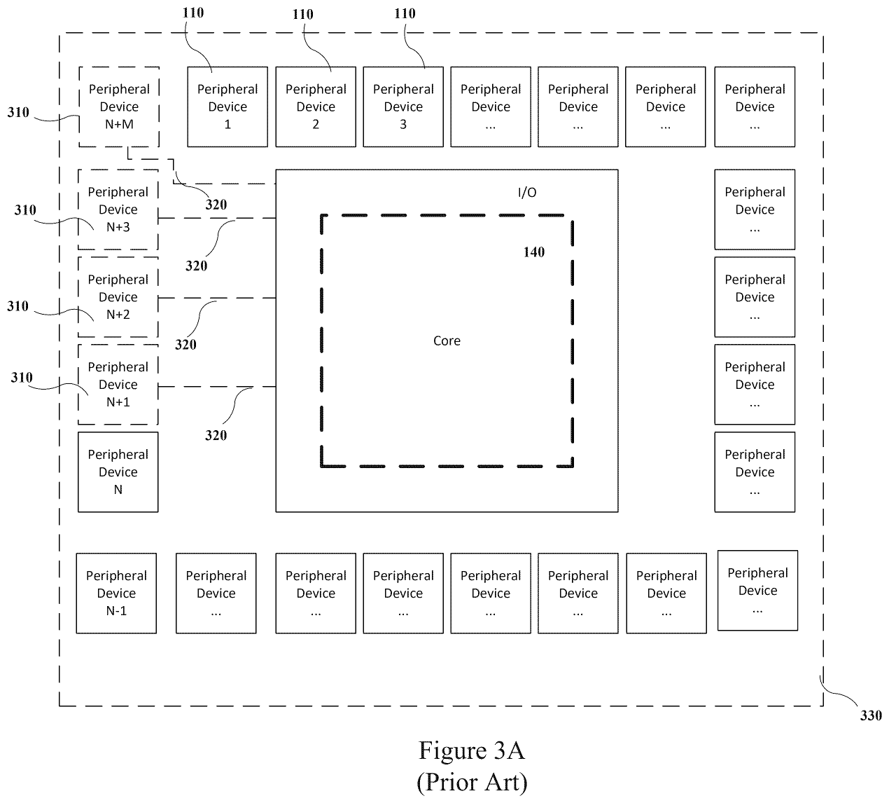

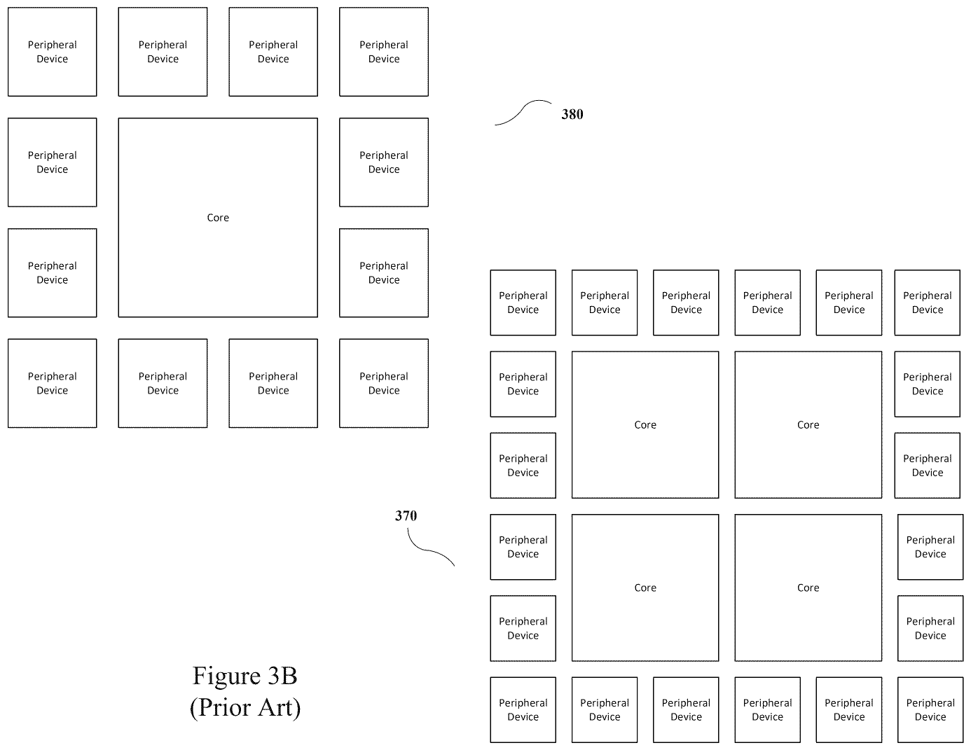

### DETAILED DESCRIPTION OF EMBODIMENTS

In the following description, for purposes of explanation, specific details are set forth to provide an understanding of the disclosure. It will be apparent, however, to one skilled in the art that the disclosure can be practiced without these details. Furthermore, one skilled in the art will recognize that embodiments of the present disclosure, described below, may be implemented in a variety of ways, such as a process, an apparatus, a system/device, or a method on a tangible computer-readable medium.

Components, elements, devices, or modules, shown in diagrams are illustrative of exemplary embodiments of the disclosure and are meant to avoid obscuring the disclosure. It shall also be understood that throughout this discussion that components may be described as separate functional units, which may comprise sub-units, but those skilled in the art will recognize that various components, or portions thereof, may be divided into separate components or may be integrated together, including integrated within a single system or component. It should be noted that functions or operations discussed herein may be implemented as components. Components may be implemented in software, hardware, or a combination thereof.

Furthermore, connections between components or systems within the figures are not intended to be limited to direct connections. Rather, data between these components may be modified, re-formatted, or otherwise changed by intermediary components. Also, additional or fewer connections may be used. It shall also be noted that the terms “coupled,” “connected,” or “communicatively coupled” shall be understood to include direct connections, indirect connections through one or more intermediary devices, and wireless connections.

Reference in the specification to “one embodiment,” “preferred embodiment,” “an embodiment,” or “embodiments” means that a particular feature, structure, characteristic, or function described in connection with the embodiment is included in at least one embodiment of the disclosure and may be in more than one embodiment. Also, the appearances of the above-noted phrases in various places in the specification are not necessarily all referring to the same embodiment or embodiments.

The use of certain terms in various places in the specification is for illustration and should not be construed as limiting. The terms “include,” “including,” “comprise,” and “comprising” shall be understood to be open terms and any lists the follow are examples and not meant to be limited to the listed items.

A service, function, or resource is not limited to a single service, function, or resource; usage of these terms may refer to a grouping of related services, functions, or resources, which may be distributed or aggregated. The use of memory, database, information base, data store, tables, hardware, and the like may be used herein to refer to system component or components into which information may be entered or otherwise recorded. The terms “data,” “information,” along with similar terms may be replaced by other terminologies referring to a group of bits and may be used interchangeably. Any headings used herein are for organizational purposes only and shall not be used to limit the scope of the description or the claims. All documents cited herein are incorporated by reference herein in their entirety.

It is noted that although embodiments described herein are given in the context of three-dimensional processing architectures, one skilled in the art will recognize that the teachings of the present disclosure are so not limited and may equally be applied to various other architectures and packages that involve a plurality of components within three-dimensional architectures.

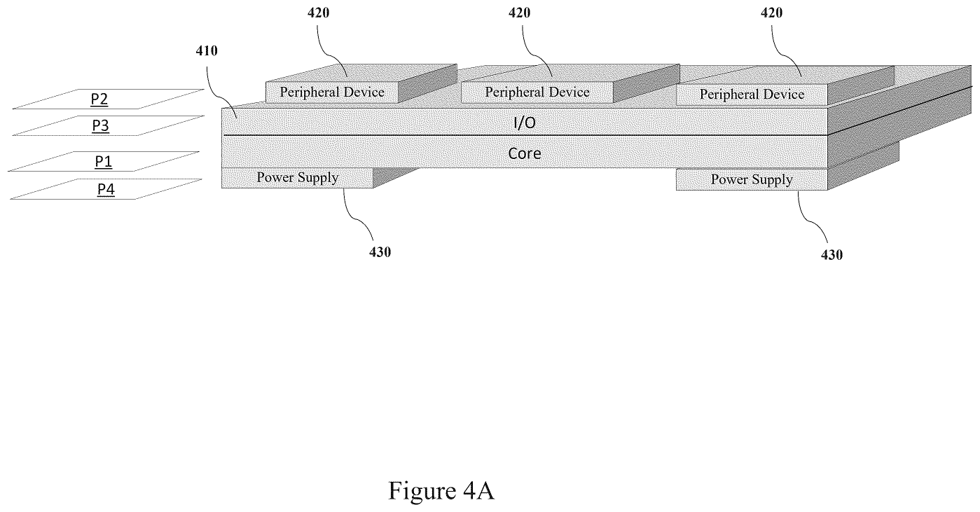

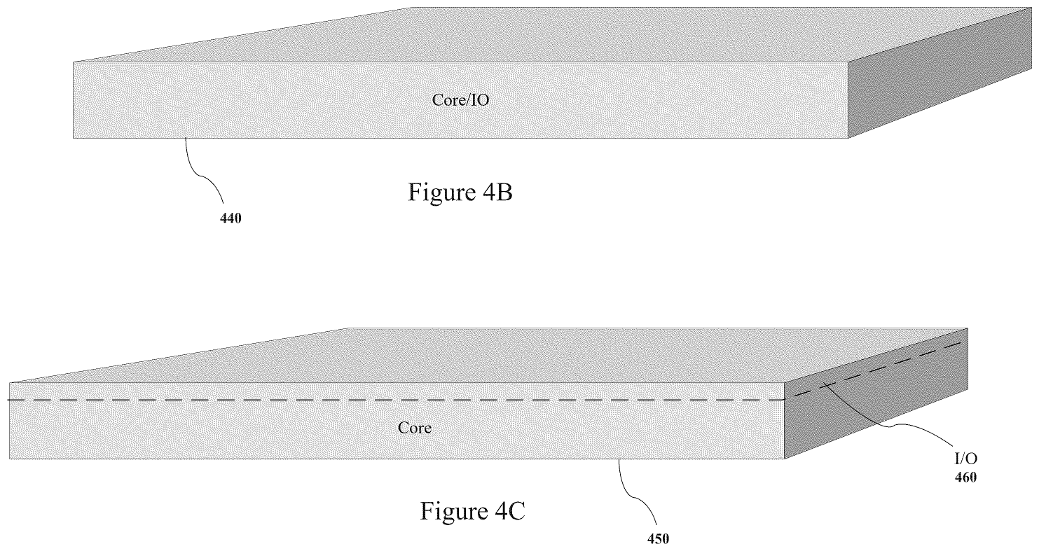

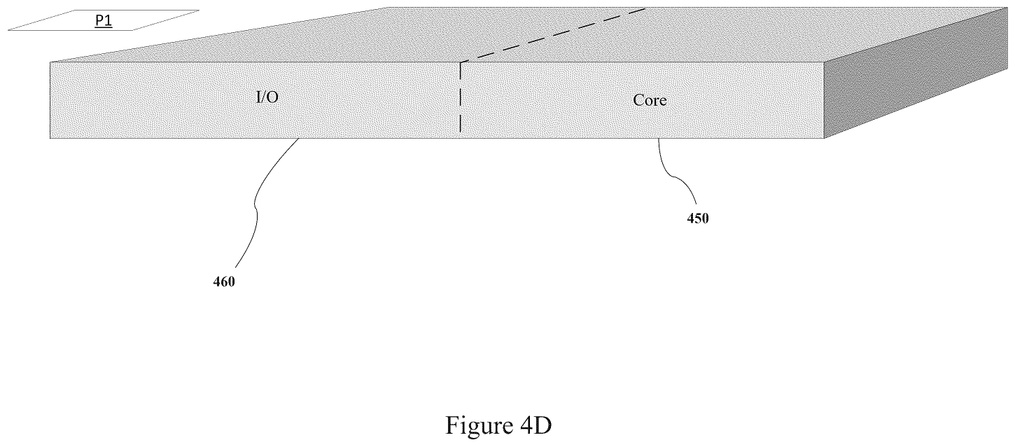

FIG. 4A illustrates an exemplary processing architecture in which peripheral devices are stacked above the processing core. As shown, the processing architecture comprises three peripheral devices 420, a processing core 410 and two power supplies 430. This architecture allows peripheral devices 420 to be vertically stacked above the core/IO 410, which provides a more dynamic ability to scale the architecture by adding additional peripherals around the core without having to increase trace distances. In certain embodiments, a substrate may be located between the core/IO 410 and power supplies 430.

The core/IO 410 comprises communication interfaces on a top surface to allow information (e.g., data and/or control) to be transmitted between a peripheral device 420 and the core 410. The core/IO 410 also comprises power interfaces that allow a power supply 430 to deliver power to the core. One skilled in the art will recognize that the number of peripheral devices positioned around the core 410 may vary across different implementations of the processing architecture.

One skilled in the art will also recognize that the core and I/O may be integrated together during manufacturing or discrete components and subsequently assembled in to the architecture and package. FIG. 4B illustrates an integrated core/IO 440 according to various embodiments of the present disclosure. FIG. 4C illustrates a discrete core 450 and discrete I/O 460 that are manufactured and subsequently stacked and assembled within the processing architecture according to various embodiments of the present disclosure.

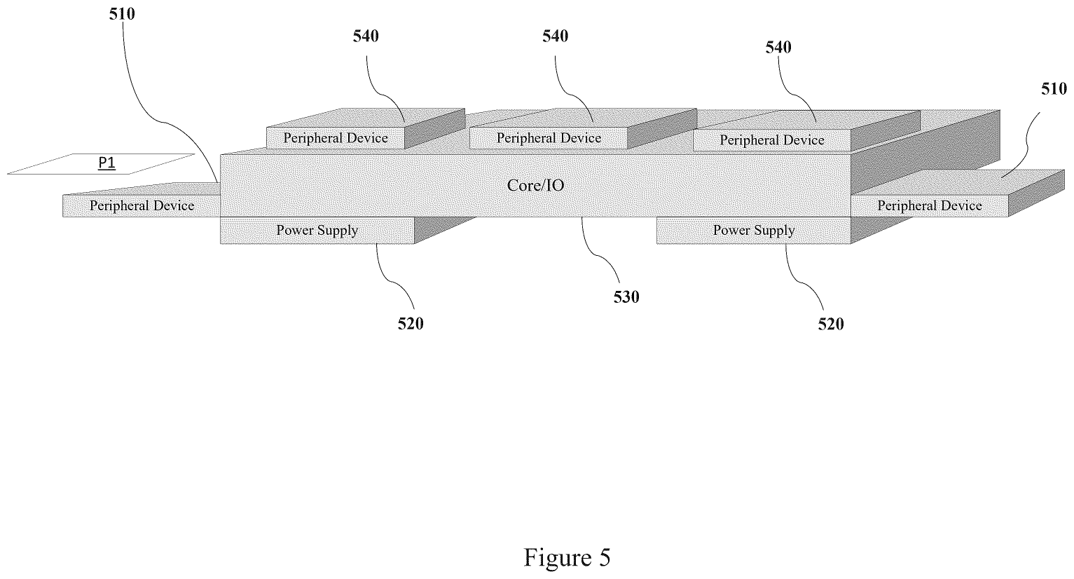

FIG. 5 illustrates a three-dimensional processing architecture according to various embodiments of the present disclosure. As shown, a processing architecture comprises a plurality of peripheral devices or circuits 540 positioned around a core/IO 530 layer across X, Y and Z planes. In one example, core/IO 530 may constitute a layer including core circuity that is provided as an integrated circuit on a semiconductor die. In another example, the core/IO 530 may include multiple semiconductor die. In a further example, the core circuitry provided on the die may be switch circuitry, a graphics processing unit (GPU), a memory, and/or a processor. In addition to the core circuitry included in core/IO layer 530, input/output (IO) circuitry, including, for example a serial deserializer circuit and/or a die-to-die interface circuitry compliant with a UCIe standard may be provided. Such IO circuitry may be provided on the same semiconductor die or different semiconductor die as the core circuitry. In the example shown in FIG. 5, three peripheral devices 540 are located vertically above the core 530 and two peripheral devices 510 are positioned horizontally adjacent to the core 530. One skilled in the art will recognize that this three-dimensional positioning of peripherals facilitates a larger number of peripherals to be located around the core 530 with reduced trace length than a two-dimensional architecture. Additionally, a three dimensional architecture provides larger surface area of the core on which peripheral I/O interfaces may be positioned. In each of the examples disclosure herein the peripheral devices may include co-packaged optics.

The processing architecture also provides for vertical positioning of power supplies 520. According to various embodiments of the present disclosure, the number and position of peripheral devices 540 and power supplies 520 around the core 530 may vary across different implementations.

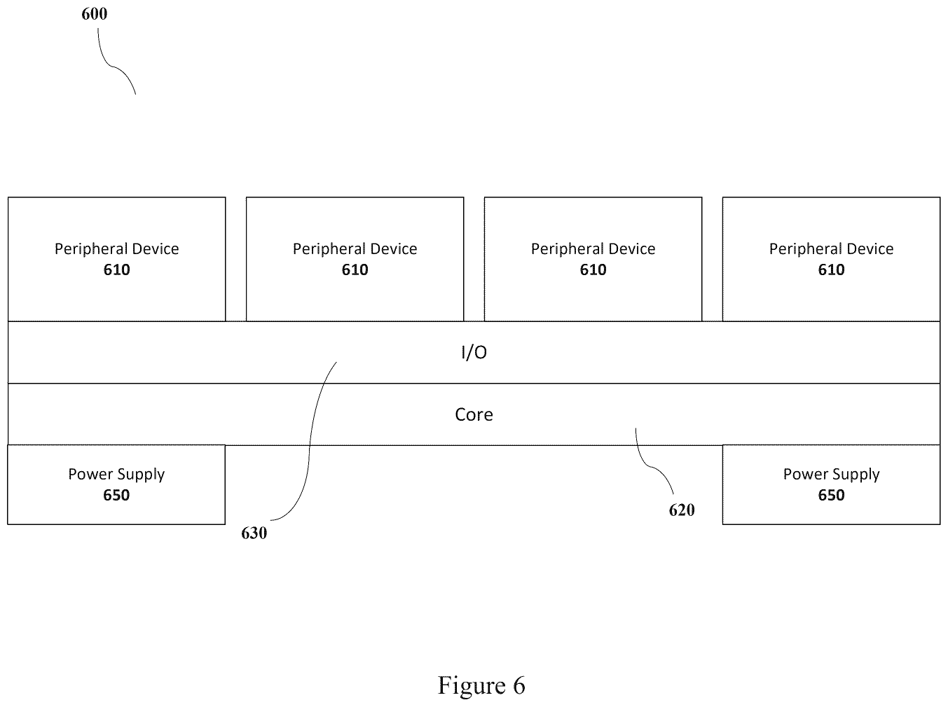

FIG. 6 illustrates a cross-section of a processing architecture according to various embodiments of the present disclosure. As shown, the processing architecture 600 comprises four peripheral devices 610, an I/O interface layer 630, a processing core 620 and two power supplies 650. Core layer 620 may itself constitute a first semiconductor substrate or die and I/O interface layer 630 may constitute a second semiconductor die, as noted above. Collectively, I/O 630 and core 620 may constitute a layer. Core circuitry 620, in one example, is operable to receive first data, process the first data, and supply second data. Returning to FIG. 4A, core circuitry 420 is preferably arranged to define a first plane P1, such that core circuitry 620, and one or more associated semiconductor die, are provided in the first plane. A plurality of peripheral devices 420 (and 610 in FIG. 6) are arranged to define a second plane P2 that is spaced from and parallel to the first plane P1, each of the plurality of peripheral devices 420 and 610 being provided in the second plane P2. Further, a plurality of input/output (I/O) circuits (630 in FIG. 6), each of which being implemented as integrated circuits on one or more semiconductor die, is arranged to define a third plane P3 between the first and second planes, the plurality of I/O circuits being operable to receive the first data from the plurality of peripheral devices and supply the first data to the core circuitry, and the plurality of I/O circuits 630 in FIG. 6 being operable to receive the second data from the core circuitry and supply the second data to the plurality of peripheral device.

The cross-sectional view shown in FIG. 5 provides a different perspective of stacked, three-dimensional embodiments of different processing architectures according to various implementations. One skilled in the art will recognize that having peripheral devices 610 and power supplies 650 vertically adjacent to the core/IO layers 620, 630 facilitates straightforward interfaces to enable information transfer and power delivery. Power supply circuits, such as power supply circuits 650 shown in FIG. 6, may be arranged in a further plane P4 spaced from and parallel to planes P1 to P3 in FIG. 4. In a further example, core circuitry 620 may constitute one or more die and I/O circuitry 630 may constitute additional semiconductor die. Thus, in a further example, core circuitry 620 may be a first die provided on a second die, which is the I/O circuitry 630. Alternatively, such first and second die may be reversed, such that the second die is on the first die.

As previously discussed, managing heat generated from the processing architecture is a critical parameter in scaling high-bandwidth implementations. The amount of heat generated from different components increases as the processing architecture scales to add more peripheral devices. Implementing heatsink functionality within a three-dimensional package may be used to address this issue across various embodiments of the present disclosure.

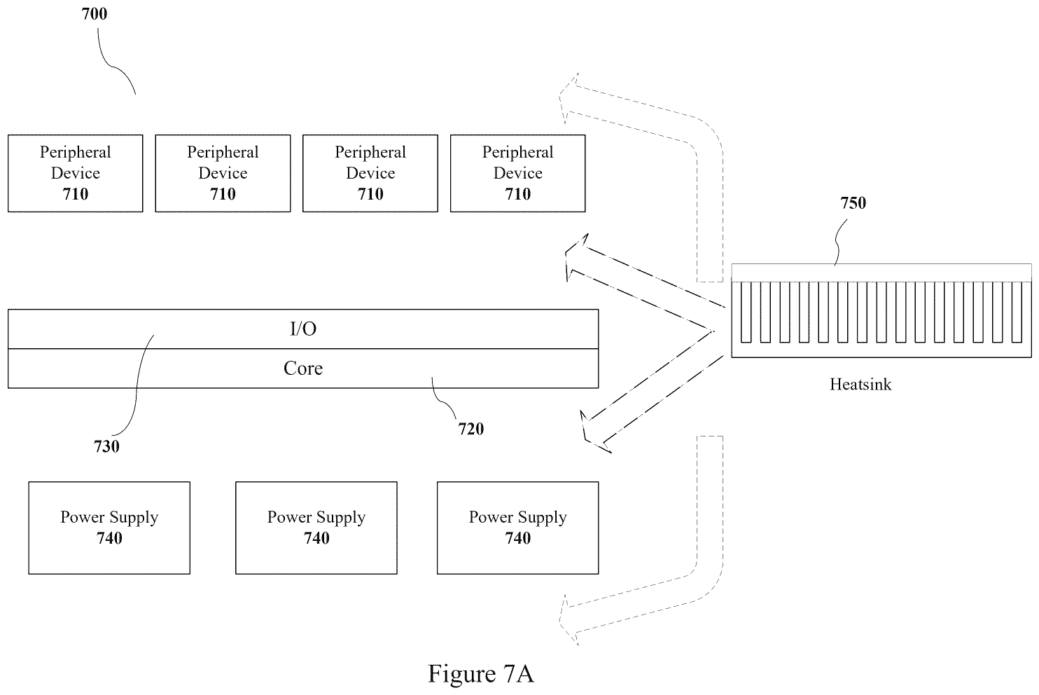

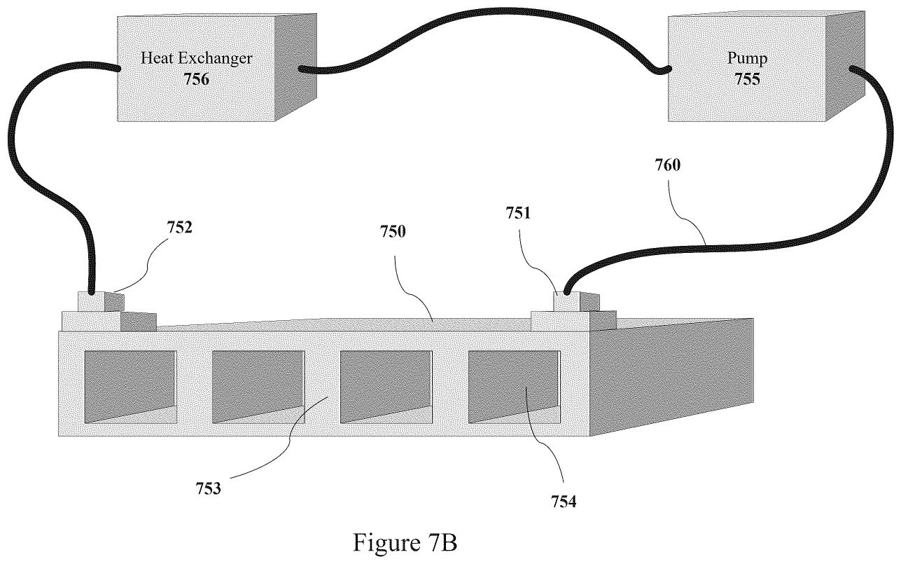

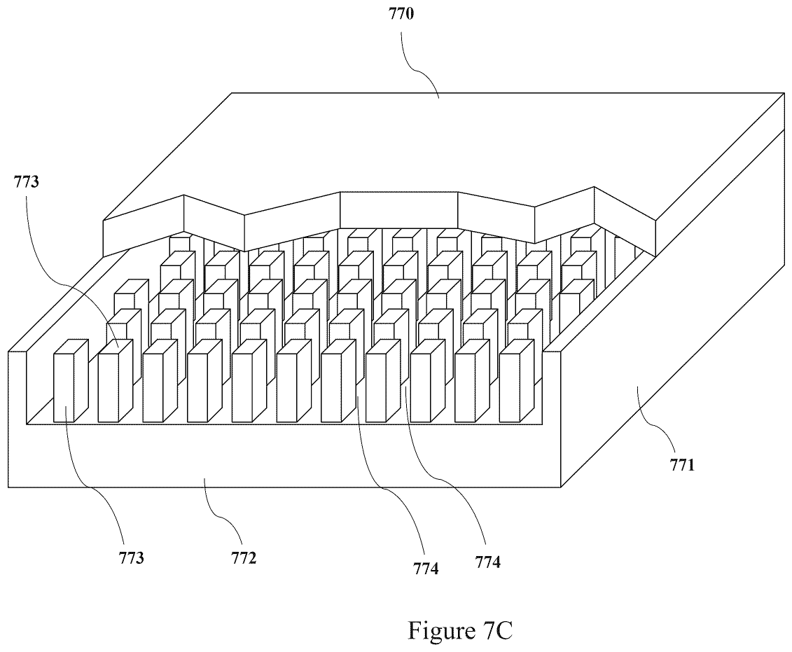

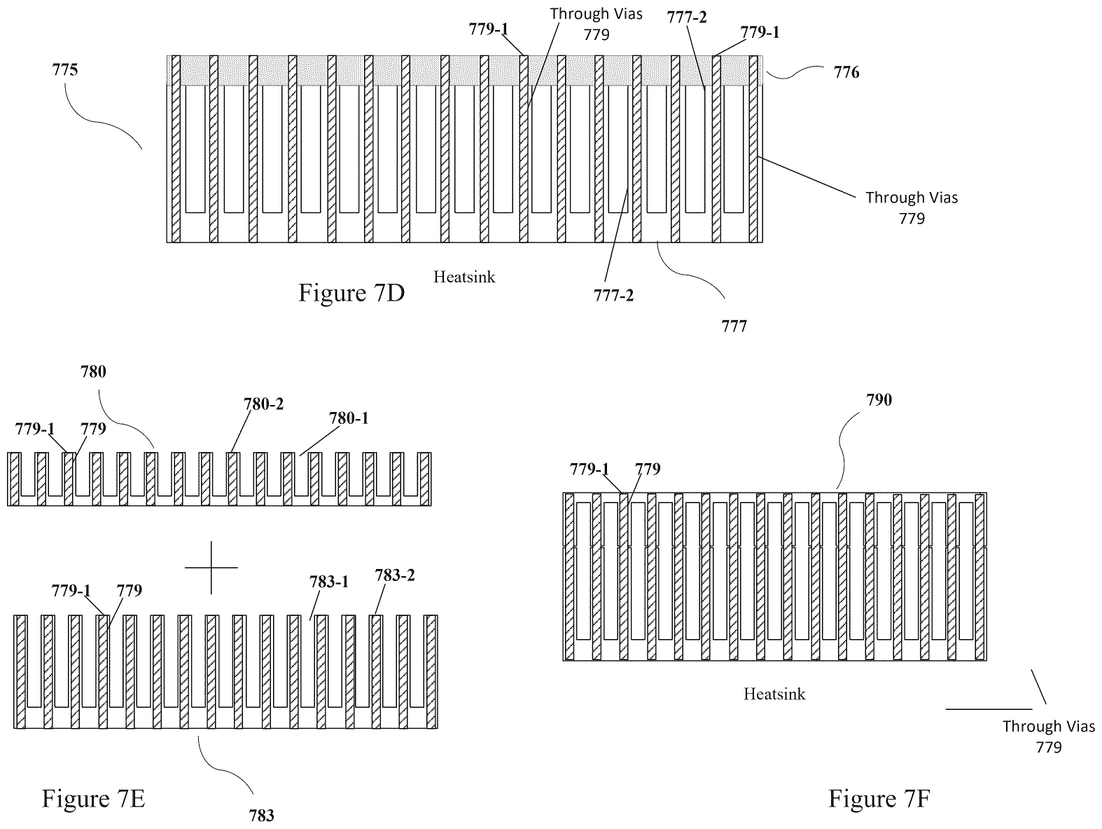

FIG. 7A illustrates different embodiments of the invention in which a heatsink is assembled within a vertical stack. In this example, a liquid heatsink 750 is positioned vertically within the stack to dissipate heat generated by other components of the processing architecture 700. As shown, a processing architecture comprises a plurality of peripheral devices 710 that may be distributed within the architecture cither horizontally, vertically or a combination thereof. A core 720 and I/O interfaces 730 are also included as either discrete elements or integrated together. A plurality of power supplies 740 are included and may be positioned horizontally, vertically or a combination thereof.

The liquid heatsink 750 may be positioned between one or more peripheral devices 710 and the core and I/O interfaces 730, 720 in one embodiment. In another embodiment, the liquid heatsink 750 is positioned between the core and I/O interfaces 730, 720 and the power supplies 740. In yet another embodiment, the liquid heatsink 750 is positioned above one or more of the peripheral devices 710. In yet another embodiment, the liquid heatsink 750 is positioned below the power supplies 740. If multiple heatsinks 750 are implemented, then they may be distributed between any of the above-described elements/layers.

In certain embodiments, liquid heatsink 750 comprises at least one inlet and one outlet to allow liquid to be pumped through the heatsink 750. The inlet(s) and outlet(s) are located on an outer surface of the package and the stacked architecture is designed to facilitate these outer surface inlet(s) and outlet(s). In this example, heatsink 750 comprises one or more enclosed cavities as shown in this cross-sectional view. More details on the heatsink inlet and outlet structures are described later in this document.

FIG. 7B illustrates an example of a liquid cooling subsystem according to various embodiments of the present disclosure. The liquid cooling subsystem comprises a heatsink structure 750, a pump 755 and a heat exchanger 756 that are coupled together by a tube 760. The heatsink structure 750 comprises an opening or inlet 751, an opening or outlet 752, at least one microfluidic cavity 754 and a plurality of micropin pillars or protrusions 753. The heatsink structure 750 is an enclosed structure to contain cooling liquid. The drawing of heatsink structure 750 in FIG. 7B shows a cross-sectional view to reveal the microfluidic cavity 754 and the micropin pillars 753. The pump 755 causes liquid to flow within the at least one microfluidic cavity 754 and to flow through the heat exchanger 756.

The heat exchanger 756 facilitates heated liquid from the heatsink structure 750 to cool. In one example, the heated liquid is cooled by another liquid flowing through another tube that is adjacent to tube 760 such that a heat transfer occurs between the two fluids. Other embodiments of the heat exchanger may be used that result in the dissipation of heat from the heated liquid that flows through the heatsink structure 750.

The heatsink structure 750 may be architected in several different ways in which liquid flows through at least one microfluidic cavity 754, is heated by heat generated within the processing architecture and subsequently cooled by the heat exchanger 756 that is external to the processing architecture. At least one microfluidic cavity 754 is structurally supported by the plurality of micropin pillars 753. The liquid heatsink can more effectively dissipate large amounts of heat generated by the high-bandwidth processing system in which it is integrated and/or packaged.

FIG. 7C illustrates one example of the cross-sectional view of a liquid heatsink structure according to various embodiments of the present disclosure. The heatsink structure comprises an upper surface 770 of a first flat portion 770-1, side surfaces 771, a bottom surface 772, a plurality of pillars or micropin pillars 773 and at least one microfluidic cavity 774. Liquid is pumped through the microfluidic cavity 774 that is heated by other elements within the three-dimensional processing architecture. This heated liquid is pumped outside of the package containing the three-dimensional processing architecture, subsequently cooled, and pumped back into the microfluidic cavity 774.

One skilled in the art will recognize that the structural design of the at least one microfluidic cavity 774 and plurality of micropin pillars 773 may vary across different embodiments within the present disclosure. For example, the micropin pillars may have a variety of different shapes, spacings and overall distribution within the liquid heatsink.

FIGS. 7D to 7F illustrate cross-sectional views of two different ways in which the liquid heatsink structure may be constructed according to various embodiments of the present disclosure. In a first example shown in FIG. 7D, the heatsink 775 comprises a first bottom portion 777 in which the microfluidic cavity is manufactured and a second top portion 776 that is a single layer, which may be flat, as shown in FIG. 7D. Bottom portion 777 may include a plurality of protrusions 777-2, such that after each portion is manufactured, the top portion 776 is positioned above the bottom portion 777 and sealed creating the enclosed microfluidic cavity. In certain embodiments, vias 779 extending through pillars or protrusions 777-2 of top portion 776 and bottom portion 777 are matched locations to provide electric conducting paths for power and signals from the bottom surface to the top surface after the top portion 776 and the bottom portion 777 are sealed together. Vias 779 may also be used to align the top (776) and bottom (779) portions of heatsink 790.

In a second example shown in FIGS. 7E and 7F, the heatsink 790 comprises a first bottom portion 783 and a second top portion 780. Both the bottom and top portions 780, 783, are manufactured such that each has a plurality of depressions or recessed portions 780-1 and 783-1, and pillars or protrusions 780-2 and 783-2, such that the microfluidic cavity is etched within each. Thereafter, the top portion 780 is flipped, positioned above the bottom portion 783 and scaled to create the enclosed microfluidic cavity. Vias 779 extend through protrusions 780-2 of the top portion 780 and through protrusions 783-2 of the bottom portion 783. Vias 779 may be provided in matched locations to provide electric conducting paths or electrical conductors, such as conductor for power and signals from the bottom surface to the top surface after the top portion 780 and the bottom portion 783 are sealed together. Moreover, vias 779 may be used to align portions 780 and 783 and the protrusions of each such portion prior to combing and scaling portions 780 and 783. In both examples, the completed heatsink structure is assembled within the processing architecture and encapsulated within a corresponding package.

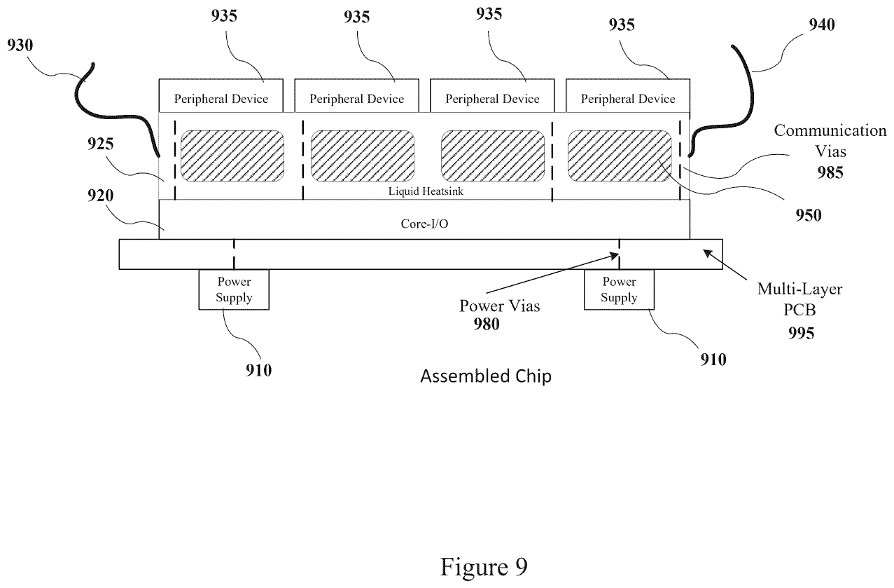

As further shown in FIGS. 7D-7F, each of vias 779 includes, in one example, an electrical conductor 779-1, such as copper, to carry or transmit electrical signals or power (current and/or voltage) carrying data. Accordingly, in the examples described below data or data carrying signals may be transmitted through the heat sink by way of electrical conductors 779-1. As further shown in these figures, each of the electrical conductors extending through a respective one of the plurality of vias in portions 780 and vias in portions 783. In the above examples, the protrusions or pillars are spaced from one another to facilitate flow of a liquid coolant between the protrusions or pillars. Moreover, in the examples discussed below with reference, for example, to FIGS. 9, 10A, 12, and 13A-13D, electrical conductors facilitate transmission of electrical signals and/or data carrying signals and thus facilitate communication between I/O circuits included in the core I/O layer and the peripheral devices. In a further example, the conductors in the heat sink may supply currents output from the power supply circuit to the Core I/O layer, which as noted above, includes the core circuitry provided on one or more semiconductor die and I/O circuitry provided on one or more other semiconductor die. As a result, such current may be provided to the core and I/O circuitry provided on such die.

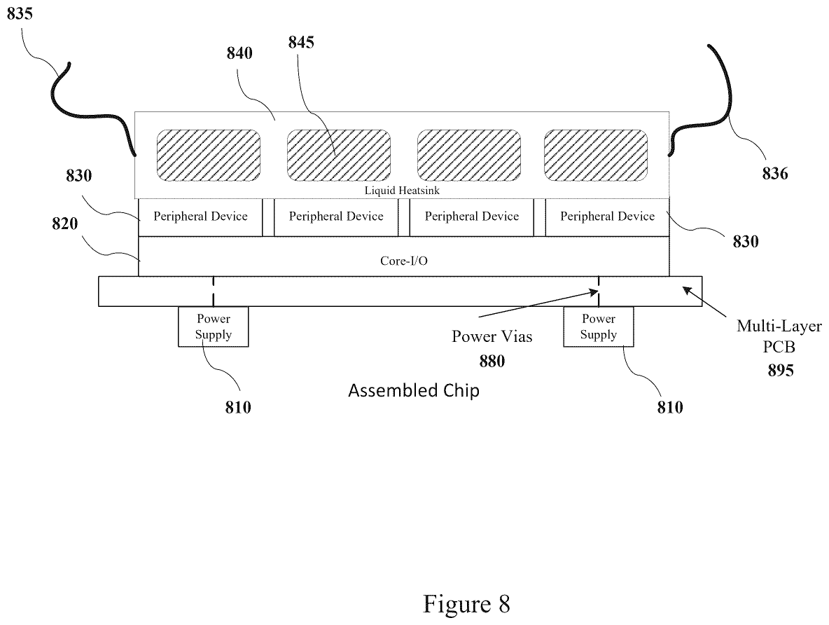

FIG. 8 illustrates a first example of a processing architecture comprising a liquid heatsink according to various embodiments of the present disclosure. As shown, the processing architecture comprises a liquid heatsink 840 as the top layer, a plurality of peripheral devices 830 below the liquid heatsink 840, a processing core and I/O interfaces 820 below the peripheral devices 830. A substrate 895 is coupled below the processing core 820. In certain embodiments, a substrate (not shown) may be located between the core 820 and the substrate 895. A plurality of power supplies 810 is positioned below the substrate 895 and coupled thereto.

A “substrate” as used herein is a structure that provides support, for example, for one or more semiconductor die or chiplets. By way of further example, a “substrate” may include one or more of a printed circuit board and may be made or organic or inorganic material, such as a resin or ceramic.

The core or core circuitry 820 performs mathematical operations, switching, and other processing of data and control information, as noted. As used herein, the core circuitry may be a semiconductor die that has integrated circuits that operate to provides such functionality. In so doing, the core 820 may leverage functional aspects of one or more peripheral devices 830 with which it interfaces using I/O interfaces, which may also constitute an additional one or more die. As further noted above, and in each of the examples disclosed herein, the core circuitry and the I/O circuitry, collectively constitute a layer, and in such layer the die having the core circuitry may be provided on the die having the I/O circuitry. Alternatively, the I/O circuitry may be provided on the die including the core circuitry.

The peripheral devices 830 may be memory elements within a distributed memory, co-processors that provide application specific operations (e.g., cryptographic and/or security co-processors), processing modules that provide mathematical specific operations (e.g., standard-based or functional specific processing such as error correction blocks, control block generation, etc.), communication modules that use electrical or optical transceivers to communicate with other devices or systems, and other supportive processing processes that may be offloaded from the processing core 820.

The liquid heatsink 840 comprises at least one microfluidic cavity 845 and micropin pillars that allow liquid to be pumped internally within the heatsink cavity 845. The liquid is heated by heat generated from the plurality of peripheral devices 830 and processing core 820. The heated liquid is subsequently pumped outside of the architecture via outlet tube 835, cooled by a heat exchanger or other cooling element, and returned with a reduced temperature via inlet tube 836. In certain embodiments, the liquid heatsink 840 is manufactured separately from other components within the architecture and inserted within the architecture using an assembly process and subsequently surrounded by a package.

A plurality of power supplies 810 provide power to the core using power vias 880 that provide a conduit through the substrate 895 such that delivery of power may be realized through a power connection within a power via 880. The power supply circuits 810, in one example, are attached to substrate 895.

The resulting architecture provides a first implementation of a highly scalable processing system that more effectively manages heat, latency, power, and footprint issues with which prior art systems currently struggle.

FIG. 9 illustrates a second example of a processing architecture comprising a liquid heatsink according to various embodiments of the present disclosure. As shown, the processing architecture comprises a plurality of peripheral devices 935 as the top layer, a liquid heatsink 925 below the plurality of peripheral devices 935, a processing core and I/O interfaces 920 below the liquid heatsink 925. A substrate 995 is coupled below the processing core 920. In certain embodiments, a substrate may be positioned between the core 920 and the substrate 995. A plurality of power supplies 910 is positioned below the substrate 995 and coupled thereto.

The core 920 performs mathematical operations, switching, and other processing of data and control information. In so doing, the core 920 may leverage functional aspects of one or more peripheral devices 935 with which it interfaces using I/O interfaces. These peripheral devices 935 may be memory elements within a distributed memory, co-processors that provide application specific operations (e.g., cryptographic and/or security co-processors), processing modules that provide mathematical specific operations (e.g., standard-based or functional specific processing such as error correction blocks, control block generation, etc.), communication modules that use electrical or optical transceivers to communicate with other devices or systems, and other supportive processing processes that may be offloaded from the processing core 920.

Similarly described relative to FIG. 8, liquid heatsink 925 comprises at least one microfluidic cavity 950 and micropin pillars that allow liquid to be pumped internally within the heatsink cavity 950. The liquid is heated by heat generated from the plurality of peripheral devices 935 and processing core 920. The heated liquid is subsequently pumped outside of the architecture via outlet tube 930, cooled by a heat exchanger or other cooling element, and returned with a reduced temperature via inlet tube 940. In certain embodiments, the liquid heatsink 925 is manufactured separately from other components within the architecture and inserted within the architecture using an assembly process and subsequently surrounded by a package.

Connectivity between the plurality of peripheral devices 935 and the core 920 is established by placing conductive material within communication vias 985 located within micropin pillars of the liquid heatsink 925. In certain embodiments, the conductive material constitutes traces or wires that run through a communication via 985 and interface with the core 920 and peripheral devices 935. As a result, the liquid heatsink 925 is directly adjacent to both the peripheral devices 935 and the core 920.

A plurality of power supplies 910 provide power to the core using power vias 980, similar to the vias noted above with respect to FIGS. 7D to 7F, that provide a conductive path or conductor for delivering power, e.g., a current, through substrate 995.

The resulting architecture provides an additional implementation of a highly scalable processing system that more effectively manages heat, latency, power, and footprint issues with which prior art systems currently struggle.

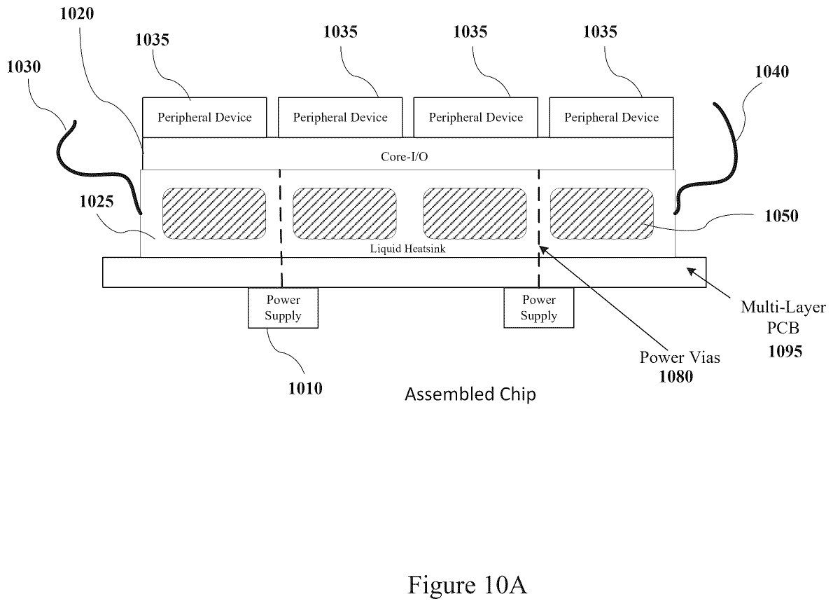

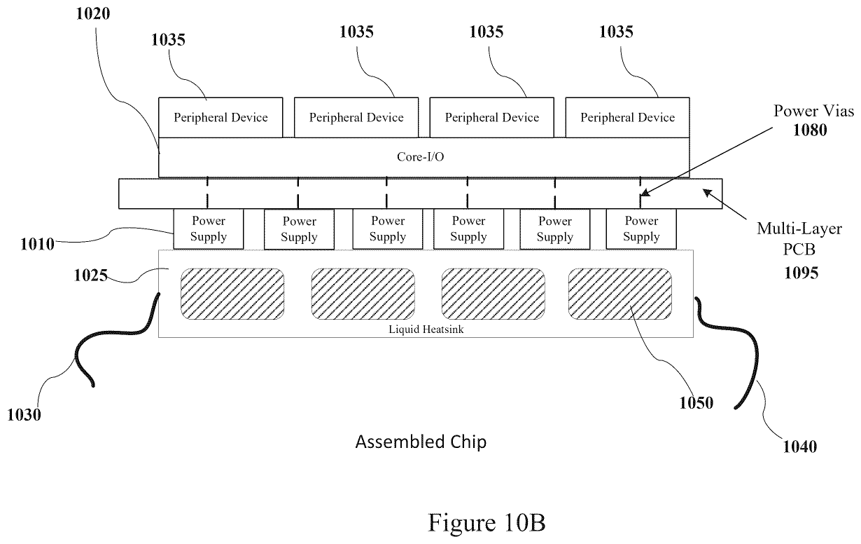

FIG. 10A illustrates a third example of a processing architecture comprising a liquid heatsink according to various embodiments of the present invention. As shown, the processing architecture comprises a plurality of peripheral devices 1035 as the top layer, a core and I/O interfaces 1020 below the peripheral devices 1035, and a liquid heatsink 1025 below the core 1020. A substrate 1095 is coupled below the liquid heatsink 1025. In certain embodiments, a substrate is positioned between the liquid heatsink 1025 and the substrate 1095. A plurality of power supplies 1010 is positioned below the substrate 1095 and coupled thereto.

Core 1020 performs mathematical operations, switching, and other processing of data and control information. In so doing, the core 1020 may leverage functional aspects of one or more peripheral devices 1035 with which it interfaces using I/O interfaces. These peripheral devices 1035 may be memory elements within a distributed memory, co-processors that provide application specific operations (e.g., cryptographic and/or security co-processors), processing modules that provide mathematical specific operations (e.g., standard-based or functional specific processing such as error correction blocks, control block generation, etc.), communication modules that use electrical or optical transceivers to communicate with other devices or systems, and other supportive processing processes that may be offloaded from the processing core 1020.

Liquid heatsink 1025 comprises at least one microfluidic cavity 1050 and micropin pillars that allow liquid to be pumped internally within the heatsink cavity 1050. The liquid is heated by heat generated from the plurality of peripheral devices 1035 and processing core 1020. The heated liquid is subsequently pumped outside of the architecture via outlet tube 1030, cooled by a heat exchanger or other cooling element, and returned with a reduced temperature via inlet tube 1040. In certain embodiments, the liquid heatsink 1025 is manufactured separately from other components within the architecture and inserted within the architecture using an assembly process and subsequently surrounded by a package.

A plurality of power supplies 1010 provide power to the core using power vias 1080 that provide a conduit including conductors noted above through the substrate 1095 and the liquid heatsink 1025 such that delivery of power, such as a current, may be realized through a power connection within a power via 1080.

The resulting architecture provides yet another implementation of a highly scalable processing system that more effectively manages heat, latency, power, and footprint issues with which prior art systems currently struggle.

FIG. 10B illustrates another processing architecture comprising a liquid heatsink according to various embodiments of the present invention. In this example, the liquid heatsink 1025 is positioned below the power supplies 1010. A substrate 1095 is located above the power supplies and the core/IO 1020 is positioned above the PCB 1095. A plurality of peripheral devices 1035 is positioned above the core/IO 1020.

Power vias 1080 through the PCB 1095 couple the power supplies 1010 to the core/IO 1020. In certain embodiments, peripheral devices interface directly with I/Os of the core 1020. As shown, the liquid heatsink 1025 has an input tube 1030 and output tube 1040 that enables the flow of liquid through the heatsink 1025.

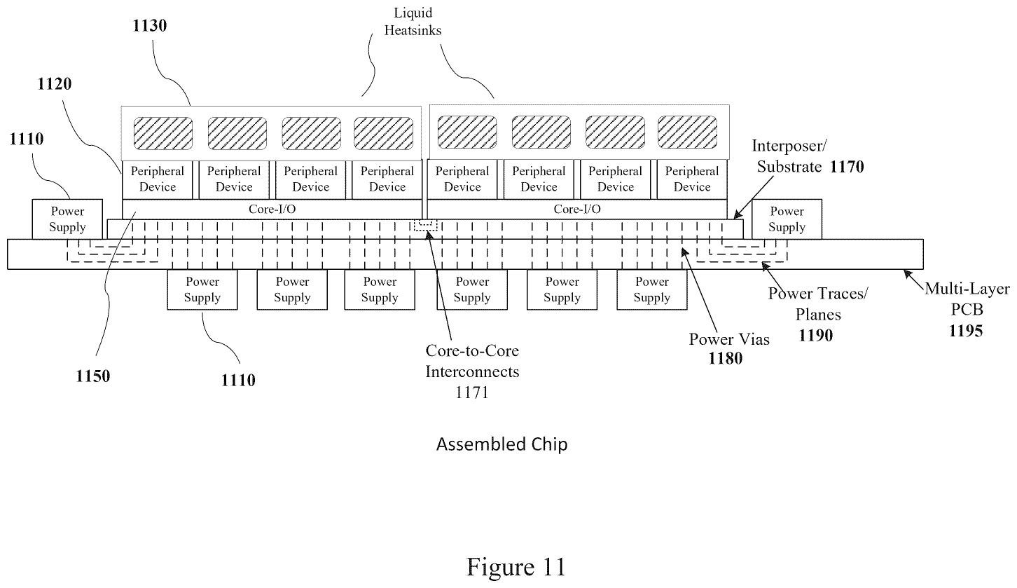

FIG. 11 illustrates a first example of a multi-core processing architecture comprising multiple liquid heatsinks according to various embodiments of the present disclosure. As shown, the multi-core processing architecture comprises a plurality of liquid heatsinks 1130, a plurality of peripheral devices 1120, a plurality of core and I/O interfaces 1150, an interposer 1170 a substrate 1195 and a plurality of power supplies 1110. The illustration shows a specific number of components within the architecture; however, one skilled in the art will recognize that a variety of different number of components may be implemented within the architecture based on various embodiments.

In this example, two liquid heatsinks 1130 are located at a top layer and have external inlet(s) and outlet(s) to facilitate pumped liquid to flow through microfluidic cavities therein. Two sets of four peripheral devices 1120 are located below the two heatsinks with a first set of peripheral devices 1120 interfacing with a first core 1150 directly below and a second set of peripheral devices 1120 interfacing with a second core 1150 directly below. In this example, the peripheral devices are located exclusively above a core; however, one skilled in the art will recognize that peripheral devices may be located in an x, y or z plane relative to the core.

An interposer/substrate 1170 is positioned below the two cores 1150 to facilitate power connections with a plurality of power supplies 1110 as well as potential core-to-core connectivity such as core-to-core interconnects 1171. A substrate 1195 is positioned below the interposer/substrate 1170.

Power supplies 1110 may be located on a top surface or bottom surface of the PCB 1195. Power vias 1180 or power traces 1190 provide power connectivity between power supplies 1110 and cores 1150. Similar to peripheral devices 1120, the power supplies 1110 may be distributed relative to x, y and z planes within the stacked architecture.

The implementation of a multi-core processor results in an increase in processing power and a larger surface area on which components, such as peripheral devices 1120 and power supplies 1110, may be distributed. The vertical stacking of components within this architecture also results in more efficient power, a decrease in relative footprint size and improved thermal performance when multiple liquid heatsinks 1130 are included in the stack.

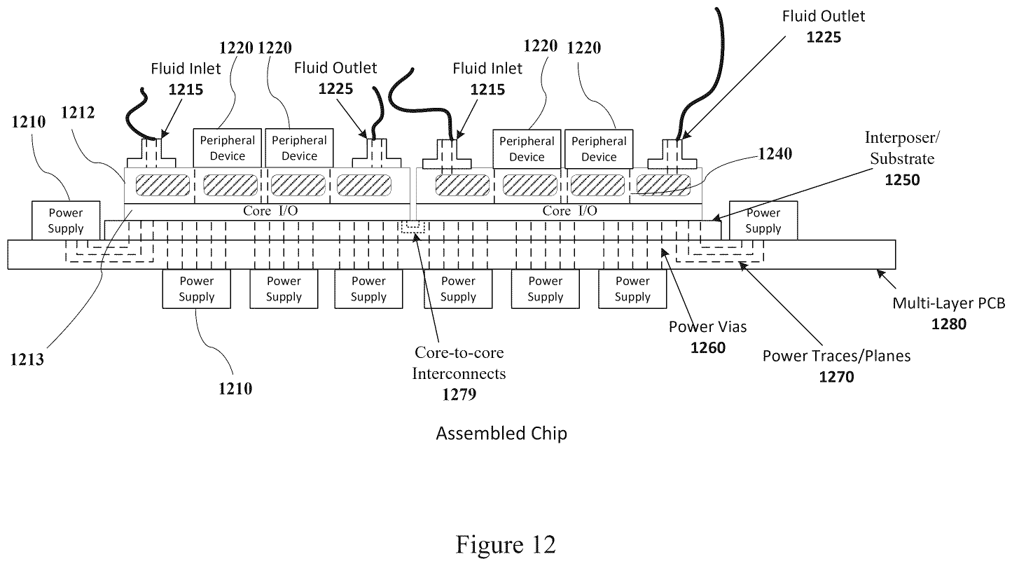

FIG. 12 illustrates a second example of a multi-core processing architecture comprising multiple liquid heatsinks according to various embodiments of the present disclosure. In this embodiment, multiple heatsinks are located in lower layers of the architecture and upward vertically extending inlet(s) and outlet(s) are used to provide an external package interface so that tubes and a pump is used to move fluid through cavities within the heatsinks. A more detailed description is provided below.

The multi-core processing architecture comprises a plurality of liquid heatsinks 1212, a plurality of peripheral devices 1220, a plurality of core and I/O interfaces 1213, an interposer/substrate 1250 a substrate 1280 and a plurality of power supplies 1210, which, in one example, are attached to substrate 1280. The illustration shows a specific number of components within the architecture; however, one skilled in the art will recognize that a variety of different number of components may be implemented within the architecture based on various embodiments.

In this example, a plurality of peripheral devices 1220 are located at a top layer across multiple liquid heatsinks 1212. Each of the liquid heatsinks 1212 has a vertically extending fluid inlet 1215 and vertically extending fluid outlet 1225 to facilitate pumped liquid to flow through microfluidic cavities 1245 therein. Multiple cores 1213 are located below the multiple fluid heatsinks 1212. These multiple cores may be coupled using core-to-core conductors or interconnects 1279 in interposer 1250 to thereby facilitate transmission of electrical signals between such cores or core circuits. “Core” and “core circuitry” are used interchangeably herein, and, as noted above, constitute a semiconductor die. Also, “I/O” and “I/O” circuitry are used interchangeably herein and, as further noted, constitute another die separate from the die having the core circuitry provided thereon, for example.

An interposer/substrate 1250 is located below the multiple cores 1213 and interface with a plurality of power supplies 1210 on a top surface and bottom surface. In this example, the peripheral devices are located exclusively above a core; however, one skilled in the art will recognize that peripheral devices may be located in an x, y or z plane relative to the core.

Power vias 1260 or power traces 1270 provide power connectivity between power supplies 1210 and cores 1213. Similar to peripheral devices 1220, the power supplies 1210 may be distributed relative to x, y and z planes within the stacked architecture. Similarly, communication vias 1240 are provided to allow communication between the cores 1213 and peripheral devices 1220.

This second implementation of a multi-core processor results in an increase in processing power and a larger surface area on which components, such as peripheral devices 1220 and power supplies 1210, may be distributed. The vertical stacking of components within this architecture also results in more efficient power, a decrease in relative footprint size and improved thermal performance when multiple liquid heatsinks 1212 are included in the stack.

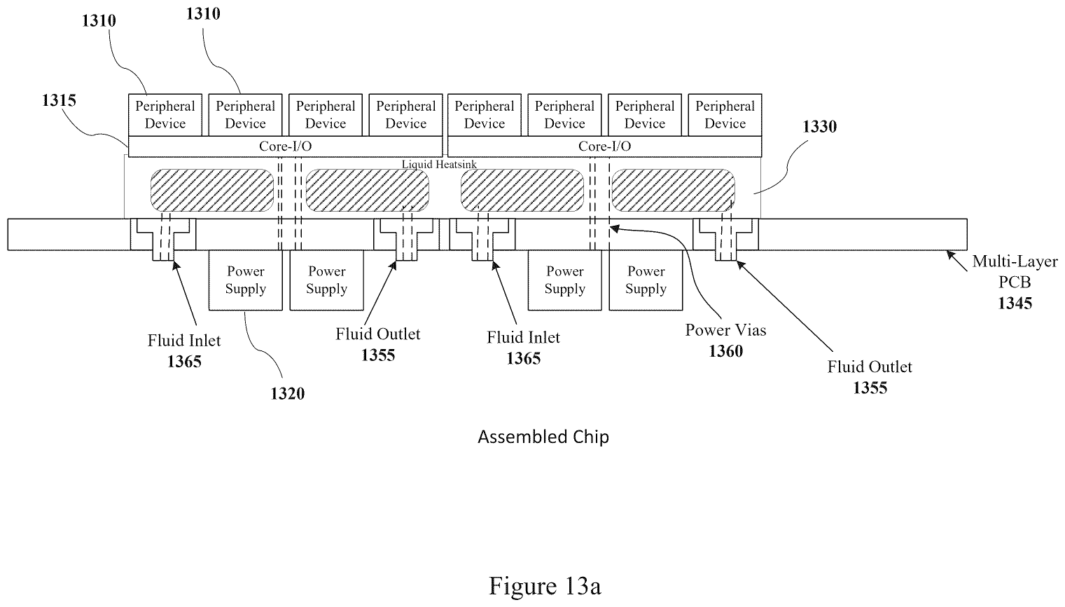

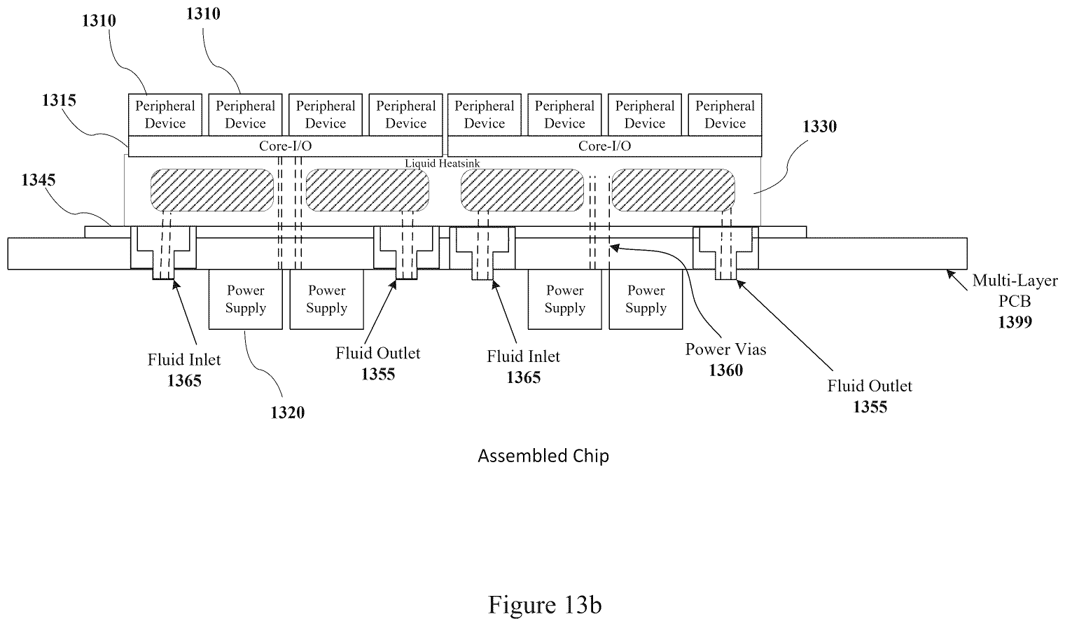

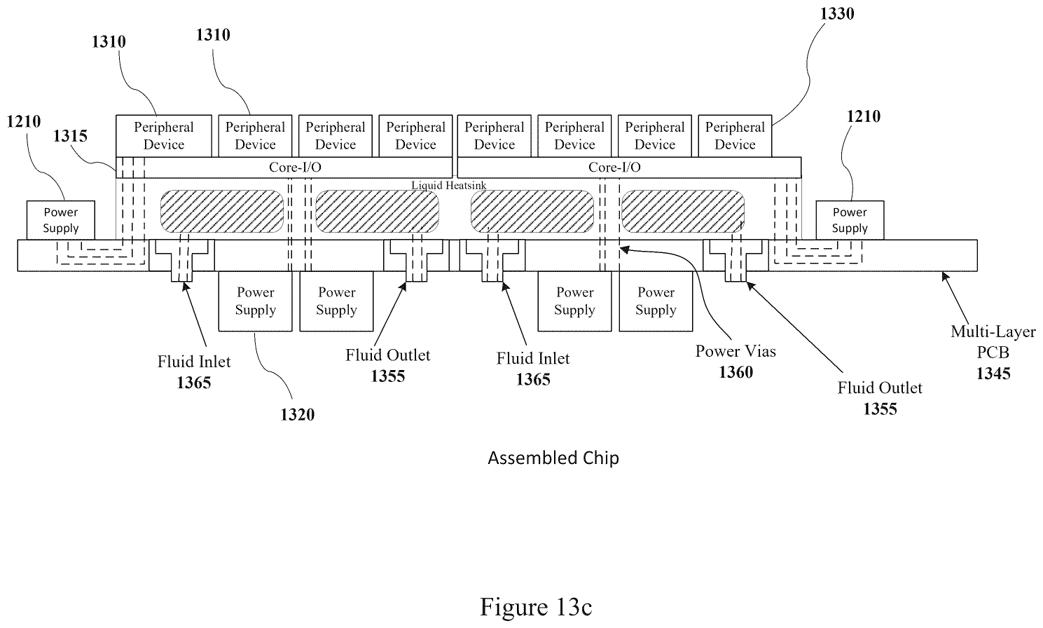

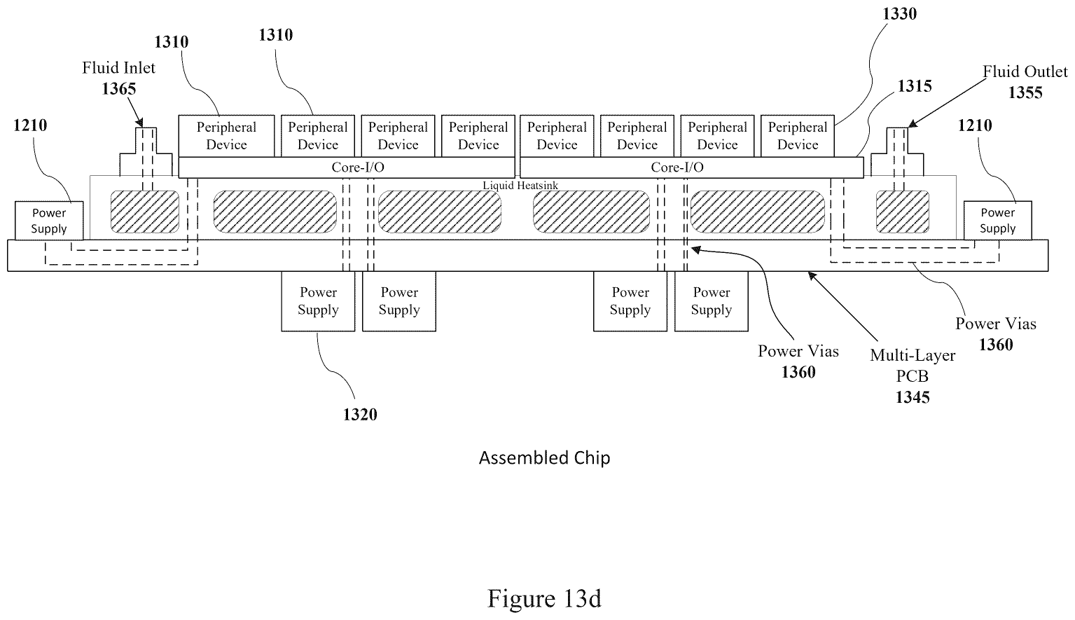

FIG. 13a illustrates a third example of a multi-core processing architecture comprising multiple liquid heatsinks according to various embodiments of the present disclosure. In this embodiment, multiple heatsinks are located in lower layers of the architecture and downward vertically extending inlet(s) and outlet(s) are used to provide an external package interface so that tubes and a pump is used to move fluid through cavities within the heatsinks.

The multi-core processing architecture comprises a plurality of liquid heatsinks 1330, a plurality of peripheral devices 1310, a plurality of core and I/O interfaces 1315, a substrate 1345 and a plurality of power supplies 1320. An interposer (not shown) between the liquid heatsink 1330 and substrate 1345 may also be implemented within the stack. The illustration shows a specific number of components within the architecture; however, one skilled in the art will recognize that a variety of different number of components may be implemented within the architecture based on various embodiments.

In this example, liquid heatsinks 1330 are located closer to the bottom of the stack. Fluid inlets 1365 and fluid outlets 1355 extend downward and provide external interfaces on the bottom of the package. Power supplies 1320 are located below the substrate 1345 and use power vias 1360 through the PCB 1345 and heatsinks 1330 to deliver power to the cores 1315. Peripheral devices 1310 are located at the top layer and interface directly with the cores 1315 that are located directly below.

This third implementation of a multi-core processor results in an increase in processing power and a larger surface area on which components, such as peripheral devices 1310 and power supplies 1320, may be distributed. The vertical stacking of components within this architecture also results in more efficient power, a decrease in relative footprint size and improved thermal performance when multiple liquid heatsinks 1330 are included in the stack.

The example shown in FIG. 13B is similar to that shown in FIG. 13A. In FIG. 13B, however, an interposer 1345 is shown between substrate 1399 and heatsink 1330. In addition, the example shown in FIG. 13C is similar to that shown in FIG. 13B. In FIG. 13C, however, additional power supplies 1210 are provided on the opposite side of substrate 1399 relative to power supplies 1320. Moreover, the example shown in FIG. 13D is similar to that shown in FIG. 13C. In FIG. 13D, however, coolant fluid inlet 1365 and coolant fluid outlet 1355 are provided on the top side of the heatsink, and connections are made from power supplies 1210 and 1320 to the Core-I/O layer (including semiconductor die having core and I/O circuitry provided thereon) by way vias and conductors 1360 through substrate 1399 and the heatsink.

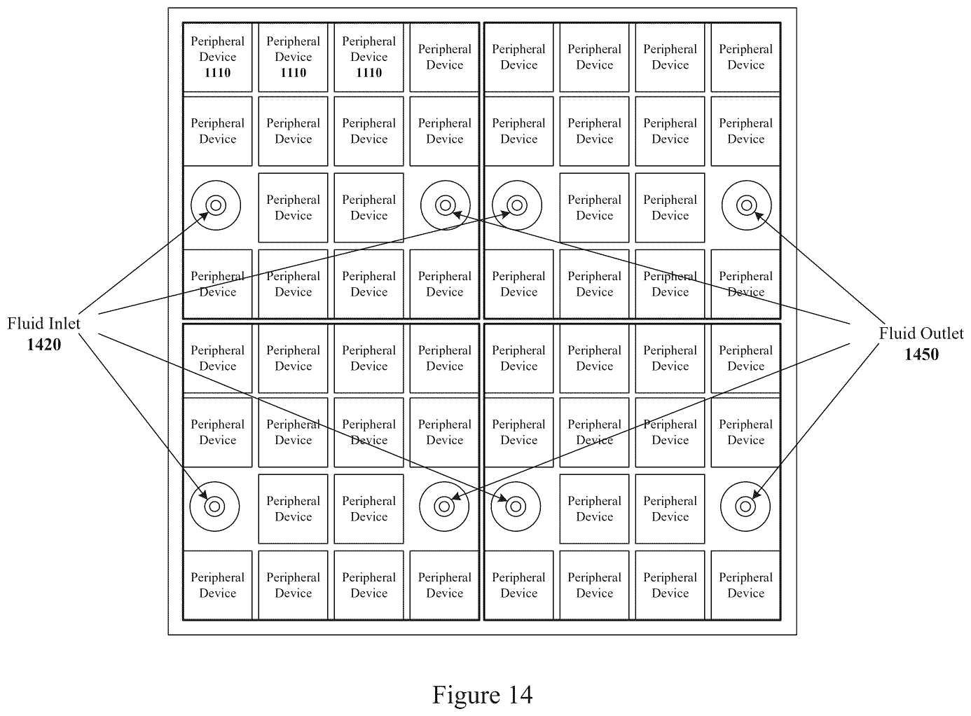

FIG. 14 illustrates a top view of a multi-core processing architecture comprising multiple liquid heatsinks according to various embodiments of the present disclosure. In this example, four cores are implemented within the architecture with corresponding peripheral device being located above at a top layer. The top layer also includes fluid inlets 1420 and fluid outlets 1450 that are used to pump liquid through the liquid heatsinks.

One skilled in the art will also recognize that a number of the elements described above may be physically and/or functionally separated into sub-modules or combined together.

It will be appreciated to those skilled in the art that the preceding examples and embodiments are exemplary and not limiting to the scope of the present disclosure. It is intended that all permutations, enhancements, equivalents, combinations, and improvements thereto that are apparent to those skilled in the art upon a reading of the specification and a study of the drawings are included within the true spirit and scope of the present disclosure. It shall also be noted that elements of any claims may be arranged differently including having multiple dependencies, configurations, and combinations.

1. An apparatus, comprising:
a layer including:
core circuitry operable to receive first data, process the first data, and supply second data, and
input/output (I/O) circuitry, at least one of the core circuitry and the input/output circuitry being arranged to define a first plane;
a plurality of peripheral devices arranged to define a second plane that is spaced from and parallel to the first plane, each of the plurality of peripheral devices being provided in the second plane; and
a heatsink provided between the first and second planes,
wherein the I/O circuitry being operable to receive the first data from the plurality of peripheral devices and supply the first data to the core circuitry, and the plurality of I/O circuits being operable to receive the second data from the core circuitry and supply the second data to the plurality of peripheral device, and wherein the I/O circuitry is configured to communicate with the peripheral devices through the heat sink.

2. An apparatus in accordance with claim 1, wherein the heat sink is thermally coupled to the core circuitry and the plurality of peripheral devices.

3. An apparatus in accordance with claim 1, wherein the heat sink includes a micro-fluidic cavity.

4. An apparatus in accordance with claim 1, wherein the heat sink includes a first opening configured to receive a coolant and a second opening configured to supply the coolant after circulating in the micro-fluidic cavity.

5. An apparatus in accordance with claim 1, wherein the heat sink includes a cavity and a plurality of protrusions included in the cavity, the plurality of protrusions being spaced from one another to facilitate coolant flow in the cavity.

6. An apparatus in accordance with claim 1, further including a substrate, the layer and the plurality of peripheral devices being provided on a first side of the substrate, the substrate having a second side opposite the first side.

7. An apparatus in accordance with claim 6, further including a plurality of power supply circuits provided on the second side of the substrate.

8. An apparatus in accordance with claim 6, further including a plurality of power supply circuits provided on the first side of the substrate.

9. An apparatus in accordance with claim 1, wherein the heat sink includes a cavity, a heat sink inlet and a heat sink outlet, and the substrate includes a first opening aligned with the heat sink inlet and a second opening aligned with the heat sink outlet, such that a coolant is supplied to the cavity of the heat sink through the first opening in the substrate and the heatsink inlet, and the coolant is output from the cavity though the heat sink outlet and the second opening.

10. An apparatus in accordance with claim 1, wherein the heat sink includes a first portion attached to a second portion, the first portion including a first recessed portion and the second portion including a second recessed portion aligned with the first recessed portion to thereby form a cavity.

11. An apparatus in accordance with claim 1, wherein the heatsink includes a first portion that is flat and a second portion that has a plurality of protrusions to thereby form a cavity within the heatsink.

12. An apparatus in accordance with 12, wherein the first portion includes a first plurality of vias and the second portion includes a second plurality of vias, each of the first plurality of vias being aligned with a corresponding one of the second plurality of vias.

13. An apparatus in accordance with claim 12, further including a plurality of electrical conductors, each of which extending through a respective one of the first plurality of vias, each of the plurality of electrical conductors further extending through a corresponding one of the second plurality of vias.

14. An apparatus in accordance with claim 1, wherein the heat sink includes a first portion and a second portion, the first portion includes a first plurality of protrusions and the second portion includes a second plurality of protrusions, wherein each of the first plurality of protrusions is aligned with a corresponding one of each of the second plurality of protrusions.

15. An apparatus in accordance with claim 1, wherein the heat sink includes a first portion and a second portion, the first portion includes a first plurality of protrusions and the second portion includes a second plurality of protrusions, each of a first plurality of vias extends through a respective one of the first plurality of protrusions and each of a second plurality of vias extends through a respective one of the second plurality of protrusions, wherein each of the first plurality of vias is aligned with a respective one of the second plurality of vias.

16. An apparatus in accordance with claim 15, further including a plurality of electrical conductors, each of which extending through a respective one of the first plurality of vias, each of the plurality of electrical conductors further extending through a corresponding one of the second plurality of vias.

17. An apparatus in accordance with claim 1, wherein the heat sink includes a first portion and a second portion, a thickness of the first portion is different than a thickness of the second portion.

18. An apparatus in accordance with claim 1, wherein the core circuitry is one of a graphics processing unit (GPU), a memory, a switch, and a processor.

19. An apparatus in accordance with claim 1, wherein each of the plurality of peripheral devices is one of a memory, a co-processor, an application-specific integrated circuit, an electrical transceiver, and an optical transceiver.

20. An apparatus in accordance with claim 1, wherein the core circuitry is arranged to define the first plane, and the I/O circuitry is arranged to define a third plane that is spaced from and parallel to the first and second planes.

21-26. (canceled)
